(19) United States
(12) Patent Application Publication
(10) Pub. No.: US 2025/0149329 A1
(43) Pub. Date: May 8, 2025

(54) SUBTRATE PROCESSING METHOD AND SUBSTRATE PROCESSING APPARATUS

(71) Applicant: TOKYO ELECTRON LIMITED, Tokyo (JP)

(72) Inventors: Ryota IFUKU, Yamanashi (JP); Takashi MATSUMOTO, Yamanashi (JP); Hiroki YAMADA, Yamanashi (JP)

(21) Appl. No.: 18/838,595

(22) PCT Filed: Feb. 6, 2023
(86) PCT No.: PCT/JP2023/003735

§ 371 Date: Aug. 14, 2024

(30) Foreign Application Priority Data
Feb. 17, 2022 (JP) 2022-022545

(51) Int. Cl. H01L 21/02; C23C 16/455

(52) U.S. Cl. CPC H01L 21/02274; C23C 16/45557; H01L 21/02115

(57) ABSTRACT

A substrate processing method includes: a preparation process of preparing a substrate having an underlying layer; a first process of forming a first graphene film, which has a first stress, on the underlying layer; a second process of forming a second graphene film, which has a second stress different from the first stress, on the first graphene film; and a third process of forming a third graphene film, which has a third stress different from the second stress, on the second graphene film.

### TECHNICAL FIELD

The present disclosure relates to a substrate processing method and a substrate processing apparatus.

### BACKGROUND

Graphene films have been technically developed for applications such as wiring and channels of field effect transistors (FET) due to unique electrical conduction properties thereof. Further, there has been proposals in recent years to apply graphene to barrier films or cap films to meet a demand for finer metal wiring. Further, in graphene film formation techniques, it has been proposed to directly form a graphene film on a silicon substrate or an insulating film under a condition of high radical density and low electron temperature using, for example, a microwave plasma chemical vapor deposition (CVD) apparatus (see, e.g., Patent Document 1).

### PRIOR ART DOCUMENTS

### Patent Document

Patent Document 1: Japanese Patent Laid-open Publication No. 2019-055887

### SUMMARY

The present disclosure provides a substrate processing method and a substrate processing apparatus, which can form a graphene film capable of improving various properties of an underlying film or a target film.

A substrate processing method according to one aspect of the present disclosure includes: a preparation process of preparing a substrate having an underlying layer; a first process of forming a first graphene film, which has a first stress, on the underlying layer; a second process of forming a second graphene film, which has a second stress different from the first stress, on the first graphene film; and a third process of forming a third graphene film, which has a third stress different from the second stress, on the second graphene film.

According to the present disclosure, it is possible to form a graphene film capable of improving various properties of an underlying film or a target film.

### BRIEF DESCRIPTION OF DRAWINGS

FIG. 1 is a schematic cross-sectional view illustrating an example of a film forming apparatus according to an embodiment of the present disclosure.

FIG. 2 is a diagram illustrating an example of a state of a substrate after forming graphene films according to the embodiment.

FIG. 3 is a diagram illustrating examples of stress caused by a graphene film with respect to a substrate.

FIG. 4 is a diagram illustrating examples of a stacking pattern of graphene films according to the embodiment.

FIG. 5 is a flowchart illustrating an example of a film forming method according to an embodiment of the present disclosure.

FIG. 6 is a diagram illustrating an example of an experimental result according to the embodiment.

### DETAILED DESCRIPTION

Hereinafter, embodiments of a substrate processing method and a substrate processing apparatus disclosed herein will be described in detail with reference to the drawings. In addition, the disclosed technique is not limited by the following embodiments.

Graphene has a structure where carbon atoms form hexagonal rings through covalent bonds, and due to the structure, graphene has unique mechanical properties of a Young's modulus up to 1,000 GPa and a fracture strength exceeding 130 GPa. Important indicators regarding properties of fine metal wiring include a resistance value, electro migration (EM) tolerance, and stress migration (SM) tolerance. These resistance value, EM tolerance, and SM tolerance are known to be strongly influenced by an interface, and bonding interface properties of the fine metal wiring with graphene become important factors. Thus, controlling the mechanical properties of graphene may become one of important parameters for the resistance value, the EM tolerance, and the SM tolerance. In other words, controlling the mechanical properties of graphene may become one of important parameters for various properties of an underlying film or a target film, which are in contact with a graphene film. Therefore, formation of a graphene film capable of improving various properties of the underlying film or the target film is expected.

### Configuration of Film Forming Apparatus 1

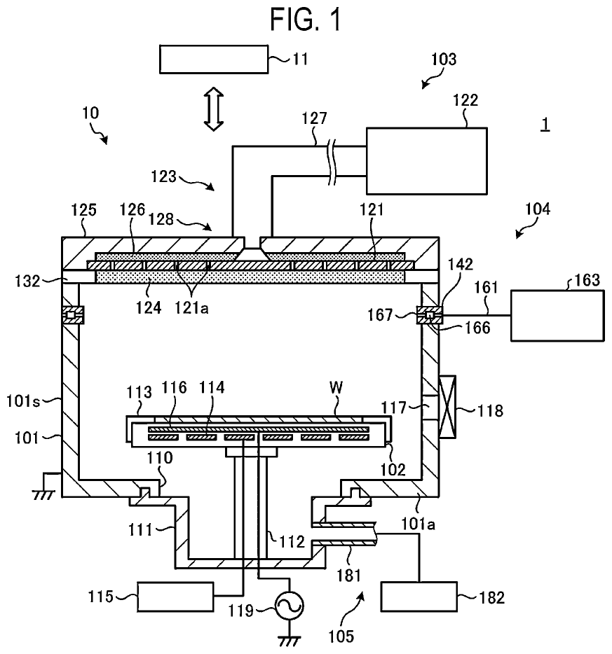

FIG. 1 is a schematic cross-sectional view illustrating an example of a film forming apparatus according to an embodiment of the present disclosure. A film forming apparatus 1 illustrated in FIG. 1 is configured as a plasma processing apparatus of, for example, an RLSA (registered trademark) microwave plasma type. In addition, the film forming apparatus 1 is an example of a substrate processing apparatus.

The film forming apparatus 1 includes an apparatus main body 10 and a controller 11 that controls the apparatus main body 10. The apparatus main body 10 includes a chamber 101, a stage 102, a microwave introduction mechanism 103, a gas supply mechanism 104, and an exhaust mechanism 105.

The chamber 101 is formed in a substantially cylindrical shape, and an opening 110 is formed at a substantially central portion of a bottom wall 101a of the chamber 101. In the bottom wall 101a, an exhaust chamber 111, which is in communication with the opening 110 and protrudes downward, is provided. In a sidewall 101s of the chamber 101, an opening 117 through which a substrate (hereinafter also referred to as “wafer”) W passes is formed. The opening 117 is opened and closed by a gate valve 118. In addition, the chamber 101 is an example of a processing container.

The substrate W, which is a processing target, is placed on the stage 102. The stage 102 has a substantially disk shape and is made of ceramics such as AIN. The stage 102 is supported by a cylindrical support 112, which is made of ceramics such as AIN and extends upward from substantially a center of a bottom of the exhaust chamber 111. An edge ring 113 is provided at an outer edge portion of the stage 102 to surround the substrate W placed on the stage 102. Further, lifting pins (not illustrated) for raising or lowering the substrate W are provided inside the stage 102 so as to be capable of protruding or retracting with respect to an upper surface of the stage 102.

In addition, a resistive heating type heater 114 is embedded in the stage 102. The heater 114 heats the substrate W placed on the stage 102 in response to power supplied from a heater power supply 115. Further, a thermocouple (not illustrated) is inserted in the stage 102, and a temperature of the substrate W is controlled within, for example, a range of 350 degrees C. to 850 degrees C. based on a signal from the thermocouple. Furthermore, an electrode 116 having substantially the same size as the substrate W is embedded in the stage 102 at a location above the heater 114, and a bias power supply 119 is electrically connected to the electrode 116. The bias power supply 119 supplies bias power having a predetermined frequency and magnitude to the electrode 116. The bias power supplied to the electrode 116 draws ions into the substrate W placed on the stage 102. In addition, the bias power supply 119 may not be provided according to characteristics of plasma processing.

The microwave introduction mechanism 103 is provided at a top portion of the chamber 101 and includes an antenna 121, a microwave output 122, and a microwave transmitter 123. In the antenna 121, a plurality of slots 121a as through-holes is formed. The microwave output 122 outputs microwaves. The microwave transmitter 123 guides the microwaves output from the microwave output 122 to the antenna 121.

A dielectric window 124 made of dielectric is provided below the antenna 121. The dielectric window 124 is supported by a support 132, which is provided in a ring shape at the top portion of the chamber 101. A wave delay plate 126 is provided on the antenna 121. A shield 125 is provided on the antenna 121. A flow path (not illustrated) is provided inside the shield 125. The shield 125 is used to cool the antenna 121, the dielectric window 124, and the wave delay plate 126 by a fluid such as water flowing through the flow path.

The antenna 121 is made of, for example, a copper plate or an aluminum plate with a surface plated in silver or gold, and the slots 121a for microwave radiation are arranged in a predetermined pattern. The arrangement pattern of the slots 121a is appropriately set to ensure even microwave radiation. A suitable example of the pattern is a radial line slot in which two slots 121a arranged in a T-shape form a pair and a plurality of pairs of slots 121a is arranged in a concentric shape. A length and an arrangement spacing of the slots 121a are appropriately determined according to an effective wavelength 2g of the microwaves. Further, the slots 121a may also have other shapes such as a circular shape and an arc shape. Furthermore, the arrangement pattern of the slots 121a is not particularly limited, and the slots 121a may be arranged, for example, in a spiral shape or a radial shape, in addition to the concentric shape. The arrangement pattern of the slots 121a is appropriately set to provide microwave radiation properties by which a desired plasma density distribution is obtained.

The wave delay plate 126 is made of dielectric having a higher dielectric constant than vacuum such as quartz, ceramics (Al₂O₃), polytetrafluoroethylene, and polyimide. The wave delay plate 126 has a function of reducing a wavelength of the microwaves compared to that in vacuum, thus reducing the antenna 121 in size. In addition, the dielectric window 124 is also made of similar dielectric.

Thicknesses of the dielectric window 124 and the wave delay plate 126 are adjusted to ensure that an equivalent circuit formed by the wave delay plate 126, the antenna 121, the dielectric window 124, and a plasma satisfies resonance conditions. By adjusting the thickness of the wave delay plate 126, a phase of the microwaves can be adjusted. By adjusting the thickness of the wave delay plate 126 to make a junction of the antenna 121 coincide with the “antinode” of standing waves, reflection of the microwaves is minimized and it is possible to maximize radiative energy of the microwaves. Further, by using the same material for the wave delay plate 126 and the dielectric window 124, interface reflection of the microwaves can be prevented.

The microwave output 122 has a microwave oscillator. The microwave oscillator may be of a magnetron type or a solid-state type. A frequency of the microwaves generated by the microwave oscillator is, for example, in a range of 300 MHz to 10 GHz. As an example, the microwave output 122 outputs microwaves of 2.45 GHz by a magnetron-type microwave oscillator. The microwaves are an example of electromagnetic waves.

The microwave transmitter 123 includes a waveguide 127 and a coaxial waveguide 128. In addition, the microwave transmitter 123 may further include a mode converter. The waveguide 127 guides the microwaves output from the microwave output 122. The coaxial waveguide 128 includes an inner conductor connected to a center of the antenna 121 and an outer conductor disposed outward of the inner conductor. The mode converter is provided between the waveguide 127 and the coaxial waveguide 128. The microwaves output from the microwave output 122 propagate within the waveguide 127 in a TE mode, and are converted from the TE mode to a TEM mode by the mode converter. The microwaves converted into the TEM mode propagate to the wave delay plate 126 via the coaxial waveguide 128, and are radiated from the wave delay plate 126 into the chamber 101 via the slots 121a of the antenna 121 and the dielectric window 124. In addition, in the waveguide 127, a tuner (not illustrated) is provided to match an impedance of a load (plasma) in the chamber 101 with an output impedance of the microwave output 122.

The gas supply mechanism 104 includes a shower ring 142 provided in a ring shape along an inner wall of the chamber 101. The shower ring 142 has a ring-shaped flow path 166 provided therein, and a plurality of discharge ports 167 connected to the flow path 166 and open inward of the shower ring 142. A gas supply 163 is connected to the flow path 166 via a pipe 161. In the gas supply 163, a plurality of gas sources and a plurality of flow controllers are provided. In one embodiment, the gas supply 163 is configured to supply at least one process gas from a corresponding gas source to the shower ring 142 via a corresponding flow controller. The gas supplied to the shower ring 142 is supplied into the chamber 101 from the discharge ports 167.

Further, when a graphene film is formed on the substrate W, the gas supply 163 supplies a carbon-containing gas, a hydrogen-containing gas, and a rare gas, which are controlled to have predetermined flow rates, into the chamber 101 via the shower ring 142. In the present embodiment, the carbon-containing gas is, for example, C₂H₂ gas. In addition, instead of or in addition to the C₂H₂ gas, for example, C₂H₄ gas, CH₄ gas, C₂H₆ gas, C₃H₈ gas, or C₃H₆ gas may be used. In addition, in the present embodiment, the hydrogen-containing gas is, for example, hydrogen gas. Further, instead of or in addition to the hydrogen gas, a halogen-based gas such as fluorine (F₂) gas, chlorine (Cl₂) gas, or bromine (Br₂) gas may be used. Further, in the present embodiment, the rare gas is, for example, Ar gas. Instead of the Ar gas, other rare gases such as He gas may be used.

The exhaust mechanism 105 includes the exhaust chamber 111, an exhaust pipe 181 provided at a sidewall of the exhaust chamber 111, and an exhaust device 182 connected to the exhaust pipe 181. The exhaust device 182 includes a vacuum pump, a pressure control valve, and the like.

The controller 11 includes a memory, a processor, and an input/output interface. The memory stores programs executed by the processor and recipes including conditions for each processing and the like. The processor executes the programs read from the memory and controls respective components of the apparatus main body 10 via the input/output interface based on the recipes stored in the memory.

For example, the controller 11 controls respective components of the film forming apparatus 1 to perform a film forming method to be described later. In a detailed example, the controller 11 executes a preparation process of loading a substrate (wafer W) having an underlying layer into the chamber 101. The controller 11 executes a first process of supplying a carbon-containing gas into the chamber 101 to form a first graphene film having a first stress on the underlying layer by using plasma of the carbon-containing gas. The controller 11 executes a second process of supplying the carbon-containing gas into the chamber 101 to form a second graphene film having a second stress different from the first stress on the first graphene film by using plasma of the carbon-containing gas. The controller 11 executes a third process of supplying the carbon-containing gas into the chamber 101 to form a third graphene film having a third stress different from the second stress on the second graphene film by using plasma of the carbon-containing gas. Here, the carbon-containing gas may be acetylene (C₂H₂) gas supplied from the gas supply 163. Further, the carbon-containing gas is not limited to acetylene. For example, the carbon-containing gas may be ethylene (C₂H₄), methane (CH₄), ethane (C₂H₆), propane (C₃H₈), propylene (C₃H₆), methanol (CH₃OH), or ethanol (C₂H₅OH).

### Stress of Graphene Film

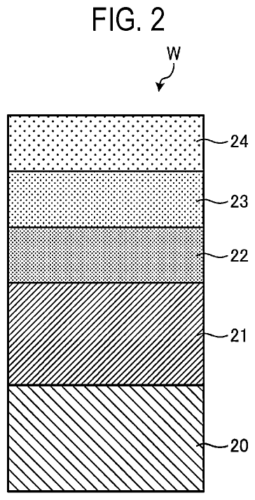

Next, a state of a substrate after forming graphene films will be described with reference to FIG. 2. FIG. 2 is a diagram illustrating an example of a state of a substrate after forming graphene films according to the present embodiment. As illustrated in FIG. 2, the wafer W has an underlying film 21 formed on a silicon substrate 20. The underlying film 21 may be, for example, a metal film used in fine metal wiring, such as copper (Cu), tungsten (W), or ruthenium (Ru), or a metal-containing film that contains the metals described above. A first graphene film 22 is formed on the underlying film 21. A second graphene film 23 is formed on the first graphene film 22. A third graphene film 24 is formed on the second graphene film 23. In other words, in the wafer W, the first graphene film 22, the second graphene film 23, and the third graphene film 24 are stacked as first to third layers on the underlying film 21.

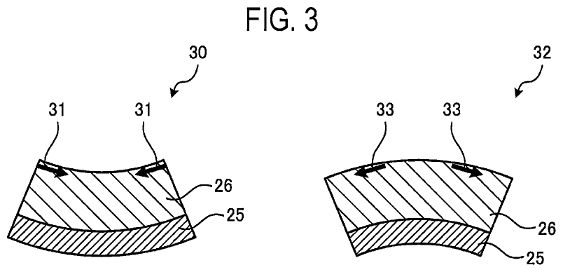

Here, stress of a graphene film will be described with reference to FIG. 3. FIG. 3 is a diagram illustrating examples of stress caused by a graphene film with respect to a substrate. State 30 illustrated in FIG. 3 depicts a state in which a graphene film 26 formed on a silicon substrate 25 has a stress 31 in a tensile direction. In other words, in State 30, the silicon substrate 25 is warped convexly downward due to the stress 31. State 32 depicts a state in which the graphene film 26 formed on the silicon substrate 25 has a stress 33 in a compressive direction. In other words, in State 32, the silicon substrate 25 is warped convexly upward due to the stress 33. In addition, the stress caused by the graphene film may be calculated using Stoney's formula by, for example, obtaining a curvature radius of the substrate upon warping before and after forming the graphene film 26 on the silicon substrate 25. Further, it is considered that the stress caused by the graphene film results from tensile stress generated by formation of grain boundaries due to bonding between crystal grains of graphene.

In the present embodiment, by controlling the stress in the tensile direction or the compressive direction with respect to each of the first to third graphene films 22 to 24 illustrated in FIG. 2, various properties of the underlying film 21 or a target film formed on the third graphene film 24 are improved. For example, the stress of the first graphene film 22 is controlled based on a lattice constant of elements that constitute the underlying film 21, a crystal plane, and the like, such that improvement mainly in electrical conduction properties is expected. Further, for example, the stress of the second graphene film 23 is controlled such that the second graphene film 23 has properties expected as a graphene bulk layer. Further, for example, the stress of the third graphene film 24 is controlled to improve interface properties such as adhesion between the third graphene film 24 and a target film (e.g., a hard mask) formed thereon in subsequent processes.

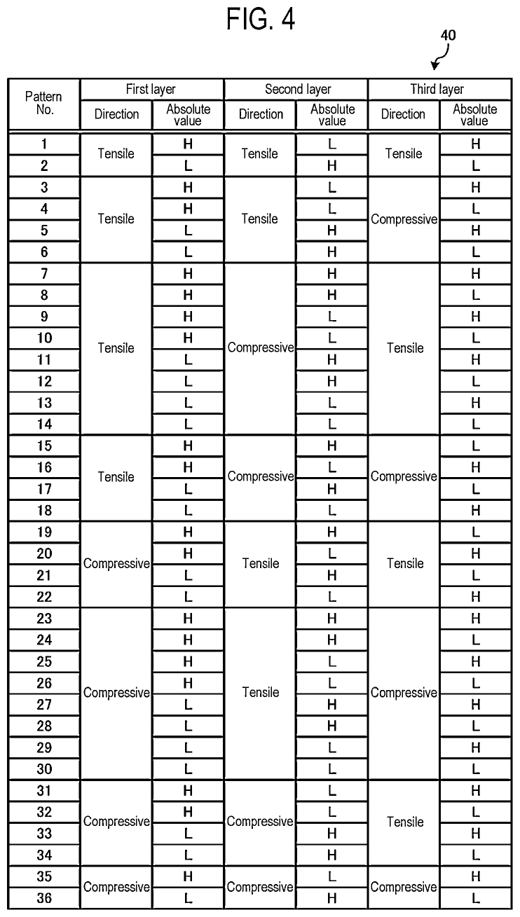

Next, stacking patterns of graphene films will be described with reference to FIG. 4. FIG. 4 is a diagram illustrating examples of a stacking pattern of graphene films according to the present embodiment. Table 40 illustrated in FIG. 4 indicates combinations of directions and absolute values of stresses of first to third layers of stacked graphene films. In cases where stresses of adjacent layers have the same direction and the same absolute value, they may be considered as a single layer. Thus, excluding stacking patterns of such cases, Table 40 indicates thirty-six combinations.

Patterns Nos. 1 and 2 represent combinations of a case where the absolute value of stress is high (denoted by “H” in FIG. 4 and the following description) and a case where the absolute value of stress is low (denoted by “L” in FIG. 4 and the following description), when the direction of stresses of the first to third layers is the tensile direction. In addition, the absolute value of stress may be relative comparison of magnitudes, and for example, it is not necessary that the absolute values denoted by “H” are the same value in FIG. 4 and the following description. Likewise, it is not necessary that the absolute values denoted by “L” are the same value in FIG. 4 and the following description.

Patterns Nos. 3 to 6 represent combinations of the absolute values of stresses of “H” and “L” when the stress direction in the first and second layers is the tensile direction and the stress direction in the third layer is the compressive direction. Patterns Nos. 7 to 14 represent combinations of the absolute values of stresses of “H” and “L” when the stress direction in the first and third layers is the tensile direction and the stress direction in the second layer is the compressive direction. Patterns Nos. 15 to 18 represent combinations of the absolute values of stresses of “H” and “L” when the stress direction in the first layer is the tensile direction and the stress direction in the second and third layers is the compressive direction.

Patterns Nos. 19 to 22 represent combinations of the absolute values of stresses of “H” and “L” when the stress direction in the first layer is the compressive direction and the stress direction in the second and third layers is the tensile direction. Patterns Nos. 23 to 30 represent combinations of the absolute values of stresses of “H” and “L” when the stress direction in the first and third layers is the compressive direction and the stress direction in the second layer is the tensile direction. Patterns Nos. 31 to 34 represent combinations of the absolute values of stresses of “H” and “L” when the stress direction in the first and second layers is the compressive direction and the stress direction in the third layer is the tensile direction. Patterns Nos. 35 and 36 represent combinations of the absolute values of stresses of “H” and “L” when the stress direction in the first to third layers is the compressive direction.

The directions and the absolute values of stresses in patterns Nos. 1 to 36 can be controlled by the carbon-containing gas, which is a precursor for graphene film formation, an internal pressure of the chamber 101 during film formation, and the like. In other words, in the present embodiment, by controlling the direction and the absolute value of each of the first to third graphene films 22 to 24, it is possible to improve various properties of the underlying film 21 or the target film formed on the third graphene film 24.

### Film Forming Method

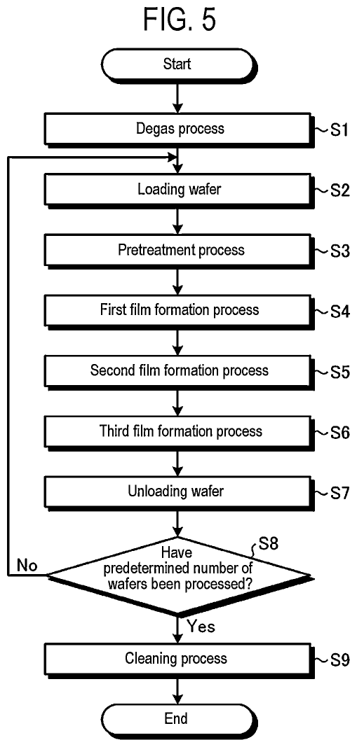

Next, film formation according to the present embodiment will be described. FIG. 5 is a flowchart illustrating an example of a film forming method according to an embodiment of the present disclosure.

In the film forming method according to the present embodiment, first, the controller 11 executes a degas process of removing residual oxygen under a state in which the chamber 101 is cleaned (step S1). The controller 11 controls the gate valve 118 to open the opening 117. While the opening 117 is open, a dummy wafer is loaded into a processing space of the chamber 101 via the opening 117 and is placed on the stage 102. The controller 11 controls the gate valve 118 to close the opening 117.

The controller 11 controls the gas supply 163 to supply a hydrogen-containing gas to the chamber 101 from the discharge ports 167. Further, the controller 11 controls the exhaust mechanism 105 to control the internal pressure of the chamber 101 to a predetermined pressure (e.g., 50 mTorr to 1 Torr). The hydrogen-containing gas in the degas process may be, for example, H₂ gas or a gas mixture of Ar and H₂. The controller 11 controls the microwave introduction mechanism 103 to ignite plasma. The controller 11 executes the degas process by using the plasma from the hydrogen-containing gas for a predetermined period of time (e.g., 120 seconds to 180 seconds). In the degas process, oxidizing components such as O₂ and H₂O remaining in the chamber 101 are discharged as OH radicals. In addition, the dummy wafer may not be used in the degas process. Further, the degas process may be omitted.

Once the degas process is completed, the controller 11 controls the gate valve 118 to open the opening 117. While the opening 117 is open, the wafer W is loaded into the processing space of the chamber 101 via the opening 117 and is placed on the stage 102. In other words, the controller 11 controls the apparatus main body 10 to load the wafer W into the chamber 101 (step S2). The controller 11 controls the gate valve 118 to close the opening 117.

The controller 11 controls the exhaust mechanism 105 to reduce the internal pressure of the chamber 101 to a predetermined pressure (e.g., 50 mTorr to 1 Torr). The controller 11 supplies a hydrogen-containing gas and a carbon-containing gas, which are plasma generation gases, to the chamber 101 from the discharge ports 167. In addition, the hydrogen-containing gas is a gas that contains hydrogen (H₂) gas and an inert gas (Ar gas). Further, the carbon-containing gas is a gas that contains a hydrocarbon gas (e.g., C₂H₂ gas) represented as CₓH_{y} (where x and y are natural numbers). Further, the controller 11 controls the microwave introduction mechanism 103 to ignite plasma. The controller 11 executes a pretreatment process of improving various properties of the interface of the underlying film 21 by using the plasma from the hydrogen-containing gas and the carbon-containing gas for a predetermined period of time (e.g., 5 seconds to 15 minutes) (step S3). For example, the pretreatment process improves adhesion between the underlying film 21 and the first graphene film 22. In addition, the plasma generation gases may be one or more of H₂ gas, CₓH_{y} gas, and Ar gas. Further, in the pretreatment process, no graphene film is formed even when the CₓH_{y} gas is supplied. In addition, the pretreatment process may be omitted.

Once the pretreatment process is completed, the controller 11 stops the application of the microwaves to stop the plasma generation. The controller 11 controls the exhaust mechanism 105 to reduce the internal pressure of the chamber 101 to a first pressure (e.g., 1 mTorr to 1 Torr). The controller 11 supplies a hydrogen-containing gas and a first carbon-containing gas, which are plasma generation gases, to the chamber 101 from the discharge ports 167. In addition, the hydrogen-containing gas is a gas that contains hydrogen (H₂) gas and an inert gas (Ar gas). Further, the inert gas may be used as the plasma generation gas instead of the hydrogen-containing gas. In addition, the first carbon-containing gas is, for example, C₂H₂ gas or C₂H₄ gas. Further, the controller 11 controls the microwave introduction mechanism 103 to ignite plasma. The controller 11 executes a first film formation process of forming the first graphene film 22 on the underlying film 21 by using the plasma from the hydrogen-containing gas and the first carbon-containing gas for a predetermined period of time (e.g., 5 seconds to 15 minutes) (step S4).

Once the first film formation process is completed, the controller 11 stops the application of the microwaves to stop the plasma generation. The controller 11 controls the exhaust mechanism 105 to reduce the internal pressure of the chamber 101 to a second pressure (e.g., 1 mTorr to 1 Torr) different from the first pressure. The controller 11 supplies the hydrogen-containing gas and the first carbon-containing gas, which are plasma generation gases, to the chamber 101 from the discharge ports 167. Further, an inert gas may be used as the plasma generation gas instead of the hydrogen-containing gas. Further, the controller 11 controls the microwave introduction mechanism 103 to ignite plasma. The controller 11 executes a second film formation process of forming the second graphene film 23 on the first graphene film 22 by using the plasma from the hydrogen-containing gas and first carbon-containing gas for a predetermined period of time (e.g., 5 seconds to 15 minutes) (step S5) In addition, in the second film forming process described above, the same first carbon-containing gas as used in the first film formation process was employed as the carbon-containing gas, but a second carbon-containing gas different from the first carbon-containing gas may be used according to respective patterns illustrated in FIG. 4. Further, in the second film formation process described above, the internal pressure of the chamber 101 was set to the second pressure, but may also be set to the first pressure according to respective patterns illustrated in FIG. 4.

Once the second film formation process is completed, the controller 11 stops the application of the microwaves to stop the plasma generation. The controller 11 controls the exhaust mechanism 105 to reduce the internal pressure of the chamber 101 to, for example, the first pressure (e.g., 1 mTorr to 1 Torr). The controller 11 supplies the hydrogen-containing gas and a second carbon-containing gas, which are plasma generation gases, to the chamber 101 from the discharge ports 167. Further, an inert gas may be used as the plasma generation gas instead of the hydrogen-containing gas. Further, the second carbon-containing gas is different from the first carbon-containing gas, and for example, C₂H₄ gas when the first carbon-containing gas is C₂H₂ gas. Further, for example, the second carbon-containing gas is C₂H₂ gas when the first carbon-containing gas is C₂H₄ gas. The controller 11 controls the microwave introduction mechanism 103 to ignite plasma. The controller 11 executes a third film formation process of forming the third graphene film 24 on the second graphene film 23 by using the plasma from the hydrogen-containing gas and second carbon-containing gas for a predetermined period of time (e.g., 5 seconds to 15 minutes) (step S6).

In addition, in the third film formation process described above, the second carbon-containing gas was used as a carbon-containing gas, but the first carbon-containing gas or another carbon-containing gas different from both the first and second carbon-containing gases may also be used according to respective patterns illustrated in FIG. 4 Further, in the third film formation process described above, the internal pressure of the chamber 101 was set to the first pressure, but may also be set to the second pressure or a pressure different from both the first and second pressures according to respective patterns illustrated in FIG. 4.

Once the third film formation process is completed, the controller 11 controls the gate valve 118 to open the opening 117. The controller 11 controls substrate support pins (not illustrated) to protrude from the upper surface of the stage 102 and raise the wafer W. While the opening 117 is open, the wafer W is unloaded from the interior of the chamber 101 by an arm of a transfer chamber (not illustrated) via the opening 117. In other words, the controller 11 controls the apparatus main body 10 to unload the wafer W from the interior of the chamber 101 (step S7).

The controller 11 determines whether a predetermined number of wafers W have been processed (step S8). In other words, after cleaning the interior of the chamber 101, the controller 11 determines whether the number of wafers W processed in the chamber 101 has reached a predetermined value. When it is determined that the predetermined number of wafers W have not been processed (step S8: “No”), the controller 11 returns to step S2 and places a next wafer W to execute the pretreatment process and the first to third film formation processes.

When it is determined that the predetermined number of wafers W have been processed (step S8: “Yes”), the controller 11 executes a cleaning process of cleaning the interior of the chamber 101 (step S9). In the cleaning process, a dummy wafer is placed on the stage 102 and a cleaning gas is supplied into the chamber 101 to clean a carbon film such as an amorphous carbon film adhered to the inner wall of the chamber 101. In addition, O₂ gas may be used as the cleaning gas, but an oxygen-containing gas such as CO gas or CO₂ gas may also be used. Further, the cleaning gas may contain a rare gas such as Ar gas. Further, the cleaning process may be executed without the dummy wafer. Once the cleaning process is completed, the controller 11 terminates the film formation. In addition, when the film formation is to be repeated, the controller 11 executes the film formation again from step S1. As described above, since the first to third film formation processes are executed while changing film formation conditions, it is possible to control the direction and the absolute value of stress of each of the first to third graphene films 22 to 24. In other words, it is possible to improve various properties of the underlying layer 21 or the target film formed on the third graphene film 24.

In addition, in the first to third film-forming processes of the above-described film forming method, plasma generation was temporarily stopped during transitions between the film formation processes, but it is also permissible to change the pressure and the components of plasma generation gases while continuing the plasma generation. Further, in the above-described film forming method, C₂H₂ gas and C₂H₄ gas were used as the first carbon-containing gas and the second carbon-containing gas, respectively, but other gases such as methane (CH₄), ethane (C₂H₆), propane (C₃H₈), propylene (C₃H₆), methanol (CH₃OH), and ethanol (C₂H₅OH) may also be used.

### Experiment Result

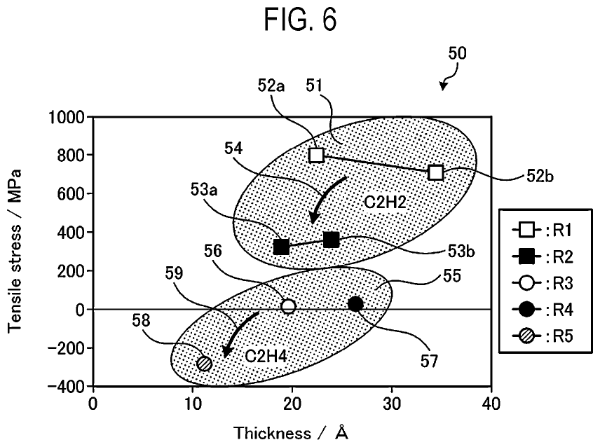

Next, an experimental result according to the present embodiment will be described with reference to FIG. 6. FIG. 6 is a diagram illustrating an example of an experimental result according to the present embodiment. Graph 50 illustrated in FIG. 6 represents stress of a graphene film under various film formation conditions. In Graph 50, the horizontal axis represents a film thickness of the graphene film, while the vertical axis represents stress of the graphene film. Further, as for the stress of the graphene film, a region having positive values represents that the stress has the tensile direction, and a region having negative values represents that the stress has the compressive direction. First, a basic film formation condition is a film formation condition R1 described below, where C₂H₂ gas is used as the carbon-containing gas.

### Film Formation Condition R1

Microwave Power: 2,200 W
Internal Pressure of Chamber: 50 mTorr
Process Gases: Ar/C₂H₂/H₂
Temperature of Wafer W: 300 degrees C. to 600 degrees C.

In the experimental result, a region 50 in Graph 50 is a region that can be obtained when using C₂H₂ gas as the carbon-containing gas. In addition, the region 51 can be changed by changing the film formation condition. A point 52a represents a stress and a film thickness when the processing time is set to 50 seconds under the film formation condition R1, the stress being 800 MPa and the film thickness being 22 angstroms. In other words, the graphene film corresponding to the point 52a has a stress of 800 MPa in the tensile direction. Further, a point 52b represents a stress and a film thickness when the processing time is set to 60 seconds under the film formation condition R1, the stress being 700 MPa and the film thickness being 34 angstroms. In other words, the graphene film corresponding to the point 52b has a stress of 700 MPa in the tensile direction.

Next, a film-forming condition where the internal pressure of the chamber 101 is changed as illustrated below compared to the film-forming condition R1 is referred to as a film-forming condition R2.

### Film Formation Condition R2

Microwave Power: 2,200 W
Internal Pressure of Chamber: 10 mTorr
Process Gas: Ar/C₂H₂/H₂
Temperature of Wafer W: 300 degrees C. to 600 degrees C.

A point 53a represents a stress and a film thickness when the processing time is set to 50 seconds under the film formation condition R2, the stress being 320 MPa and the film thickness being 19 angstroms. In other words, the graphene film corresponding to the point 53a has a stress of 320 MPa in the tensile direction. Further, a point 53b represents a stress and a film thickness when the processing time is set to 60 seconds under the film formation condition R2, the stress being 360 MPa and the film thickness being 24 angstroms. In other words, the graphene film corresponding to the point 53b has a stress of 360 MPa in the tensile direction.

When comparing the film formation condition R1 and the film formation condition R2, although the same C₂H₂ gas is used as the carbon-containing gas, by reducing the internal pressure of the chamber 101, the stress of the graphene film can be reduced from 800 MPa and 700 MPa to 320 MPa and 360 MPa, respectively, as indicated by an arrow 54. In other words, the stresses of the respective graphene films formed under combination of the film formation conditions R1 and R2 can be associated with the absolute values of stress “H” and “L” illustrated in FIG. 4.

Next, a film formation condition where the carbon-containing gas is changed as described below compared to the film formation condition R1 is referred to as a film formation condition R3. Further, a film formation condition where a flow rate of the process gas is changed compared to the film formation condition R3 (the flow rate is made greater than in the film formation condition R3) is referred to as a film formation condition R4. In addition, in the film formation condition R4, the carbon-containing gas of the film formation condition R1 is replaced with C₂H₄ gas, and the flow rate of the process gas is the same as in the film formation condition R1.

### Film Formation Condition R3

Microwave Power: 2,200 W
Internal Pressure of Chamber: 50 mTorr
Process Gas: Ar/C₂H₄/H₂
Temperature of Wafer W: 300 degrees C. to 600 degrees C.

### Film Formation Condition R4

Microwave Power: 2,200 W
Internal Pressure of Chamber: 50 mTorr
Process Gas: Ar/C₂H₄/H₂
Temperature of Wafer W: 300 degrees C. to 600 degrees C.

In the experimental result, a region 55 in Graph 50 is a region that can be obtained when using C₂H₄ gas as the carbon-containing gas. In addition, in the region 55, stress can be changed by changing the film formation condition (changing the flow rate of the C₂H₄ gas). A point 56 represents a stress and a film thickness when the processing time is set to 50 seconds under the film formation condition R3, the stress being 19 MPa and the film thickness being 20 angstroms. In other words, the graphene film corresponding to the point 56 has a stress of 19 MPa in the tensile direction. A point 57 represents a stress and a film thickness when the processing time is set to 50 seconds under the film formation condition R4, the stress being 33 MPa and the film thickness being 26 angstroms. In other words, the graphene film corresponding to the point 56 has a stress of 33 MPa in the tensile direction.

Next, a film formation condition where the internal pressure of the chamber 101 is changed as described below compared to the film formation conditions R3 and R4 is referred to as a film formation condition R5.

### Film Formation Condition R5

Microwave Power: 2,200 W
Internal Pressure of Chamber: 10 mTorr
Process Gas: Ar/C₂H₄/H₂
Temperature of Wafer W: 300 degrees C. to 600 degrees C.

A point 58 represents a stress and a film thickness when the processing time is set to 50 seconds under the film formation condition R5, the stress being −280 MPa and the film thickness being 11 angstroms. In other words, the graphene film corresponding to the point 58 has a stress of 280 MPa in the compressive direction.

When comparing the film formation conditions R3 and R4 with the film formation condition R5, although the same C₂H₄ gas is used as the carbon-containing gas, by reducing the internal pressure of the chamber 101, the stress of the graphene film can be changed from 19 MPa and 33 MPa to-280 MPa and from the tensile direction to the compressive direction, as indicated by an arrow 54. In other words, the stresses of respective graphene films formed under the combination of the film formation condition R3 or R4 and the film formation condition R5 can be associated with the absolute value of stress “L” in the “tensile” direction and the absolute value of stress “L” or “H” in the “compressive” direction, which are illustrated in FIG. 4.

Further, focusing, for example, on the point 52a, the point 53a, and the point 56, it can be recognized that it is possible to change the stresses of the graphene films with substantially the same film thickness. Furthermore, for example, since the point 52a, the point 53a, and the point 58 are associated with the absolute value of stress “H” in the “tensile” direction, the absolute value of stress “L” in the “tensile” direction, and the absolute value of stress “H” in the “compressive” direction, respectively, they correspond to the stacking pattern of Pattern No. 3 illustrated in FIG. 4. In other words, in the present embodiment, by adjusting the film formation conditions of the first to third film formation processes, it is possible to form the first to third graphene films 22 to 24 that correspond to the respective patterns illustrated in FIG. 4.

As described above, according to the present disclosure, the substrate processing apparatus (film forming apparatus 1) includes the processing container (chamber 101) capable of accommodating the substrate W having the underlying layer (underlying film 21), and the controller 11. The controller 11 executes: a preparation process of preparing the substrate W; a first process of forming the first graphene film 22, which has a first stress, on the underlying layer; a second process of forming the second graphene film 23, which has a second stress different from the first stress, on the first graphene film 22; and a third process of forming the third graphene film 24, which has a third stress different from the second stress, on the second graphene film 23. As a result, it is possible to form graphene films (the first graphene film 22 to the third graphene film 24) capable of improving various properties of the underlying film 21 or a target film.

Further, according to the present disclosure, the first stress and the second stress have the same direction and different absolute values. As a result, it is possible to form the second graphene film 23 with a film quality different from that of the first graphene film 22.

Further, according to the present disclosure, the first stress and the second stress are both a compressive stress in which a direction of the stress is a compressive direction. As a result, it is possible to form the second graphene film 23 with a film quality different from that of the first graphene film 22.

Further, according to the present disclosure, the first stress and the second stress are both a tensile stress in which a direction of the stress is a tensile direction. As a result, it is possible to form the second graphene film 23 with a film quality different from that of the first graphene film 22.

Further, according to the present disclosure, the first stress and the second stress have different directions and different absolute values. As a result, it is possible to form the second graphene film 23 with a film quality different from that of the first graphene film 22.

Further, according to the present disclosure, the first stress is a compressive stress in which a direction of the stress is a compressive direction, and the second stress is a tensile stress in which a direction of the stress is a tensile direction. As a result, it is possible to form the second graphene film 23 with a film quality different from that of the first graphene film 22.

Further, according to the present disclosure, the first stress is a tensile stress in which a direction of the stress is a tensile direction, and the second stress is a compressive stress in which a direction of the stress is a compressive direction. As a result, it is possible to form the second graphene film 23 with a film quality different from that of the first graphene film 22.

Further, according to the present disclosure, the second stress and the third stress have the same direction and different absolute values. As a result, it is possible to form the third graphene film 24 with a film quality different from that of the second graphene film 23.

Further, according to the present disclosure, the second stress and the third stress have different directions and different absolute values. As a result, it is possible to form the third graphene film 24 with a film quality different from that of the second graphene film 23.

Further, according to the present disclosure, the first process forms the first graphene film 22 at a first pressure by using plasma from a process gas containing a first carbon-containing gas. As a result, it is possible to form the first graphene film 22 capable of improving electrical conduction properties with respect to the underlying film 21.

Further, according to the present disclosure, the second process forms the second graphene film 23 at a second pressure different from the first pressure, by using the plasma from the process gas containing the first carbon-containing gas. As a result, it is possible to form the second graphene film 23 with a film quality different from that of the first graphene film 22. Further, it is possible to form the second graphene film 23 having properties expected as a graphene bulk layer.

Further, according to the present disclosure, the third process forms the third graphene film 24 at the first pressure by using plasma from a process gas containing a second carbon-containing gas different from the first carbon-containing gas. As a result, it is possible to form the third graphene film 24 with a film quality different from that of the second graphene film 23. Further, it is possible to form the third graphene film 24 capable of improving the interface properties with the target film formed on the third graphene film 24 in subsequent processes.

Further, according to the present disclosure, the first process forms the first graphene film 22 at the second pressure by using the plasma from the process gas containing the first carbon-containing gas. As a result, it is possible to form the first graphene film 22 capable of improving the electrical conduction properties with respect to the underlying film 21.

Further, according to the present disclosure, the second process forms the second graphene film 23 at the first pressure by using the plasma from the process gas containing the second carbon-containing gas different from the first carbon-containing gas. As a result, it is possible to form the second graphene film 23 with a film quality different from that of the first graphene film 22. Further, it is possible to form the second graphene film 23 having properties expected as a graphene bulk layer.

Further, according to the present disclosure, the third process forms the third graphene film 24 at the second pressure different from the first pressure, by using the plasma from the process gas containing the second carbon-containing gas different from the first carbon-containing gas. As a result, it is possible to form the third graphene film 24 with a film quality different from that of the second graphene film 23. Further, it is possible to form the third graphene film 24 capable of improving the interface properties with the target film formed on the third graphene film 24 in subsequent processes.

Further, according to the present disclosure, the first pressure is in a range of 1 mTorr to 1 Torr. As a result, it is possible to form graphene films (the first to third graphene films 22 to 24) capable of improving various properties of the underlying film 21 or the target film.

Further, according to the present disclosure, the second pressure is in a range of 1 mTorr to 1 Torr. As a result, it is possible to form graphene films (the first to third graphene films 22 to 24) capable of improving various properties of the underlying film 21 or the target film.

Further, according to the present embodiment, the first carbon-containing gas and the second carbon-containing gas may be any of acetylene (C₂H₂), ethylene (C₂H₄), methane (CH₄), ethane (C₂H₆), propane (C₃H₈), propylene (C₃H₆), methanol (CH₃OH), and ethanol (C₂H₅OH). As a result, it is possible to form graphene films (the first to third graphene films 22 to 24) capable of improving various properties of the underlying film 21 or the target film.

The embodiments disclosed herein should be considered to be exemplary and not limitative in all respects. The above embodiments may be omitted, replaced, or modified in various ways without departing from the scope of the appended claims and the spirit thereof.

Further, in the above embodiments, stacking patterns of graphene films in three layers have been described, but the present disclosure is not limited thereto. For example, the graphene films may be stacked in a stacking pattern in which four or more layers are stacked while adjacent layers have different film qualities (stresses).

Further, in the above-described embodiments, the film forming apparatus 1 that performs processing such as etching or film formation on the wafer W by using microwave plasma as a plasma source has been described by way of example, but the technique of the present disclosure is not limited thereto. The plasma source is not limited to the microwave plasma as long as the apparatus performs processing on the wafer W by using plasma, and any plasma source such as capacitively-coupled plasma, inductively-coupled plasma, or magnetron plasma may be used.

In addition, the present disclosure may also have the following configuration.
(1) A substrate processing method comprising:
   a preparation process of preparing a substrate having an underlying layer;
   a first process of forming a first graphene film, which has a first stress, on the underlying layer;
   a second process of forming a second graphene film, which has a second stress different from the first stress, on the first graphene film; and
   a third process of forming a third graphene film, which has a third stress different from the second stress, on the second graphene film.
(2) The substrate processing method described in (1), wherein the first stress and the second stress have the same direction and different absolute values.
(3) The substrate processing method described in (2), wherein the first stress and the second stress are both a compressive stress in which a direction of the stress is a compressive direction.
(4) The substrate processing method described in (2), wherein the first stress and the second stress are both a tensile stress in which a direction of the stress is a tensile direction.
(5) The substrate processing method described in (1), wherein the first stress and the second stress have different directions and different absolute values.
(6) The substrate processing method described in (5), wherein the first stress is a compressive stress in which a direction of the stress is a compressive direction, and the second stress is a tensile stress in which a direction of the stress is a tensile direction.
(7) The substrate processing method described in (5), wherein the first stress is a tensile stress in which a direction of the stress is a tensile direction, and the second stress is a compressive stress in which a direction of the stress is a compressive direction.
(8) The substrate processing method described in any one of (2) to (7), wherein the second stress and the third stress have the same direction and different absolute values.
(9) The substrate processing method described in any one of (2) to (7), wherein the second stress and the third stress have different directions and different absolute values.
(10) The substrate processing method described in any one of (1) to (9), wherein the first process forms the first graphene film at a first pressure by using plasma from a process gas containing a first carbon-containing gas.
(11) The substrate processing method described in (10), wherein the second process forms the second graphene film at a second pressure different from the first pressure, by using the plasma from the process gas containing the first carbon-containing gas.
(12) The substrate processing method described in (11), wherein the third process forms the third graphene film at the first pressure by using plasma from a process gas containing a second carbon-containing gas different from the first carbon-containing gas.
(13) The substrate processing method described in any one of (1) to (9), wherein the first process forms the first graphene film at a second pressure by using plasma from a process gas containing a first carbon-containing gas.
(14) The substrate processing method described in (10) or (13), wherein the second process forms the second graphene film at the first pressure by using plasma from a process gas containing a second carbon-containing gas different from the first carbon-containing gas.
(15) The substrate processing method described in (11) or (14), wherein the third process forms the third graphene film at the second pressure different from the first pressure, by using the plasma from the process gas containing the second carbon-containing gas different from the first carbon-containing gas.
(16) The substrate processing method described in any one of (10) to (12), (14), and (15), wherein the first pressure is in a range of 1 mTorr to 1 Torr.
(17) The substrate processing method described in any one of (11) to (13) and (15), wherein the second pressure is in a range of 1 mTorr to 1 Torr.
(18) The substrate processing method described in any one of (10) to (17), wherein the first carbon-containing gas and the second carbon-containing gas are any of acetylene (C₂H₂), ethylene (C₂H₄), methane (CH₄), ethane (C₂H₆), propane (C₃H₈), propylene (C₃H₆), methanol (CH₃OH), and ethanol (C₂H₅OH).
(19) A substrate processing apparatus comprising:
   a processing container capable of accommodating a substrate having an underlying layer; and
   a controller,
   wherein the controller is configured to control the substrate processing apparatus to prepare the substrate,
   wherein the controller is configured to control the substrate processing apparatus to form a first graphene film, which has a first stress, on the underlying layer,
   wherein the controller is configured to control the substrate processing apparatus to form a second graphene film, which has a second stress different from the first stress, on the first graphene film, and
   wherein the controller is configured to control the substrate processing apparatus to form a third graphene film, which has a third stress different from the second stress, on the second graphene film.

### EXPLANATION OF REFERENCE NUMERALS

1: film forming apparatus, 11: controller, 20: silicon substrate, 21: underlying film, 22: first graphene film, 23: second graphene film, 24: third graphene film, 101: chamber, 102: stage, W: wafer

1. A substrate processing method comprising:
a preparation process of preparing a substrate having an underlying layer;
a first process of forming a first graphene film, which has a first stress, on the underlying layer;
a second process of forming a second graphene film, which has a second stress different from the first stress, on the first graphene film; and
a third process of forming a third graphene film, which has a third stress different from the second stress, on the second graphene film.

2. The substrate processing method of claim 1, wherein the first stress and the second stress have the same direction and different absolute values.

3. The substrate processing method of claim 2, wherein the first stress and the second stress are both a compressive stress in which a direction of the stress is a compressive direction.

4. The substrate processing method of claim 2, wherein the first stress and the second stress are both a tensile stress in which a direction of the stress is a tensile direction.

5. The substrate processing method of claim 1, wherein the first stress and the second stress have different directions and different absolute values.

6. The substrate processing method of claim 5, wherein the first stress is a compressive stress in which a direction of the stress is a compressive direction, and the second stress is a tensile stress in which a direction of the stress is a tensile direction.

7. The substrate processing method of claim 5, wherein the first stress is a tensile stress in which a direction of the stress is a tensile direction, and the second stress is a compressive stress in which a direction of the stress is a compressive direction.

8. The substrate processing method of claim 2, wherein the second stress and the third stress have the same direction and different absolute values.

9. The substrate processing method of claim 2, wherein the second stress and the third stress have different directions and different absolute values.

10. The substrate processing method of claim 1, wherein the first process forms the first graphene film at a first pressure by using plasma from a process gas containing a first carbon-containing gas.

11. The substrate processing method of claim 10, wherein the second process forms the second graphene film at a second pressure different from the first pressure, by using the plasma from the process gas containing the first carbon-containing gas.

12. The substrate processing method of claim 11, wherein the third process forms the third graphene film at the first pressure, by using plasma from a process gas containing a second carbon-containing gas different from the first carbon-containing gas.

13. The substrate processing method of claim 1, wherein the first process forms the first graphene film at a second pressure by using plasma from a process gas containing a first carbon-containing gas.

14. The substrate processing method of claim 10, wherein the second process forms the second graphene film at the first pressure, by using plasma from a process gas containing a second carbon-containing gas different from the first carbon-containing gas.

15. The substrate processing method of claim 11, wherein the third process forms the third graphene film at the second pressure different from the first pressure, by using plasma from a process gas containing a second carbon-containing gas different from the first carbon-containing gas.

16. The substrate processing method of claim 10, wherein the first pressure is in a range of 1 mTorr to 1 Torr.

17. The substrate processing method of claim 11, wherein the second pressure is in a range of 1 mTorr to 1 Torr.

18. The substrate processing method of claim 12, wherein the first carbon-containing gas and the second carbon-containing gas are any of acetylene (C₂H₂), ethylene (C₂H₄), methane (CH₄), ethane (C₂H₆), propane (C₃H₈), propylene (C₃H₆), methanol (CH₃OH), and ethanol (C₂H₅OH).

19. A substrate processing apparatus comprising:
a processing container capable of accommodating a substrate having an underlying layer; and
a controller,
wherein the controller is configured to control the substrate processing apparatus to prepare the substrate,
wherein the controller is configured to control the substrate processing apparatus to form a first graphene film, which has a first stress, on the underlying layer,
wherein the controller is configured to control the substrate processing apparatus to form a second graphene film, which has a second stress different from the first stress, on the first graphene film, and
wherein the controller is configured to control the substrate processing apparatus to form a third graphene film, which has a third stress different from the second stress, on the second graphene film.
